(19) United States
(12) Patent Application Publication
(10) Pub. No.: US 2010/0108636 A1
(43) Pub. Date: May 6, 2010

(54) Integrated Tool for Fabricating an Electronic Component

(75) Inventors: Xilin Peng, Bloomington, MN (US); Jiaoming Qiu, St. Paul, MN (US); Yonghua Chen, Edina, MN (US); Michael Christopher Kautzky, Eagan, MN (US); Mark Thomas Kief, Lakeville, MN (US)

Correspondence Address: SEAGATE TECHNOLOGY LLC;C/O WESTMAN, CHAMPLIN & KELLY, P.A., SUITE 1400, 900 SECOND AVENUE SOUTH, MINNEAPOLIS, MN, 55402-3244, US

(73) Assignee: SEAGATE TECHNOLOGY LLC, Scotts Valley, CA (US)

(21) Appl. No.: 12/493,468

(22) Filed: Jun. 29, 2009

Related U.S. Application Data
(60) Provisional application No. 61/109,797, filed on Oct. 30, 2008.

(51) Int. Cl. B44C 1/22; C23F 1/08; C23C 14/34; C23C 14/56

(52) U.S. Cl. 216/13; 156/345.1; 156/345.31; 204/192.38; 204/192.11; 204/298.04; 204/298.02

(57) ABSTRACT

A tool for use in fabricating an electronic component includes a plurality of processing modules and a transfer chamber in communication with each of the plurality of processing modules. The transfer chamber includes a component for transferring a structure to each of the plurality of processing modules. The plurality of processing modules and the transfer chamber are sealed from the surrounding environment and are under a vacuum. The plurality of processing modules includes a first module configured to perform a first process on the structure and a second module configured to perform a second process on the structure. The first process includes performing at least one shaping operation on the structure.

### CROSS-REFERENCE TO RELATED APPLICATION

The present application is based on and claims the benefit of U.S. provisional patent application Ser. No. 61/109,797, filed Oct. 30, 2008, the content of which is hereby incorporated by reference in its entirety.

### BACKGROUND

With the never-ending need to increase the areal density of a storage device, the width of magnetic transducers, such as reader sensors and write poles are becoming smaller to enable the write and read back of the smaller track and bit sizes on a medium.

Both reader sensors and write poles are defined via some type of micro fabrication, such as ion beam etching (IBE). However, after the reader sensor and the write pole are defined, formation of reaction zones or dead layers of an uncontrolled thickness occur on the sides of the device. Formation of these dead layers can be caused by various reasons. For example, an argon beam bombards the sidewalls of the device during ion milling and can cause ion induced physical damage. In another example, after the reader sensor and the write pole are defined by ion milling, these devices are exposed to atmosphere for transition to other fabricating processes. Due to the atmospheric exposure of the freshly ion milled device, oxygen and water moisture can readily react with the device edges. In yet another example, subsequent oxidation to the sidewalls can occur during alumina insulation or other insulation/encapsulation layer formation process.

These dead layers have a reduced magnetic moment. In the case of a write pole, dead layers can cause the write pole to write more curved transitions compared to a write pole without dead layers. In the case of a reader, the resistance of the device can vary depending on the thickness of the dead layer and, therefore, the edge effect of the reader is critical. Controlling or eliminating an edge reaction zone in write poles and readers is important for performance control.

The discussion above is merely provided for general background information and is not intended to be used as an aid in determining the scope of the claimed subject matter.

### SUMMARY

A tool for use in fabricating an electronic component, such as a transducer, includes a plurality of processing modules and a transfer chamber in communication with each of the plurality of processing modules. The transfer chamber includes a robotically moveable arm for transferring a structure to each of the plurality of processing modules. The plurality of processing modules and the transfer chamber are sealed from the surrounding environment and are under a vacuum. The plurality of processing modules includes a first module configured to perform a first process on the structure and a second module configured to perform a second process on the structure. The first process includes performing at least one shaping operation to the structure.

The structure includes a layered magnetic device formed on a substrate or structure. After the structure is placed within the tool, the structure is transferred into the first module. After the at least one shaping operation is performed on the structure, the structure is transferred from the first module to the second module for undergoing the second process without breaking the vacuum.

These and various other features and advantages will be apparent from a reading of the following Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

FIG. 1 illustrates a partial sectional view of an example read/write transducer for perpendicular recording to a medium.

FIG. 2 illustrates a diagrammatic air bearing surface view of one embodiment of a reader sensor.

FIG. 3 illustrates a diagrammatic air bearing surface view of one embodiment of a write pole.

FIG. 4 illustrates a block diagram of an integrated tool for forming one of a reader sensor and a write pole such as to eliminate the formation of reaction zones or dead layers on sidewall of the read sensor or the write pole

FIG. 5 illustrates diagrammatic view of the integrated tool illustrated in FIG. 4.

### DETAILED DESCRIPTION

Embodiments of the disclosure pertain to the minimization of edge reaction zones of a magnetic device by integrating both device definition and subsequent protective layer deposition in an integrated tool without breaking vacuum. Such an approach allows a thickness of an edge reaction zone to be controlled/eliminated compared with conventional processes.

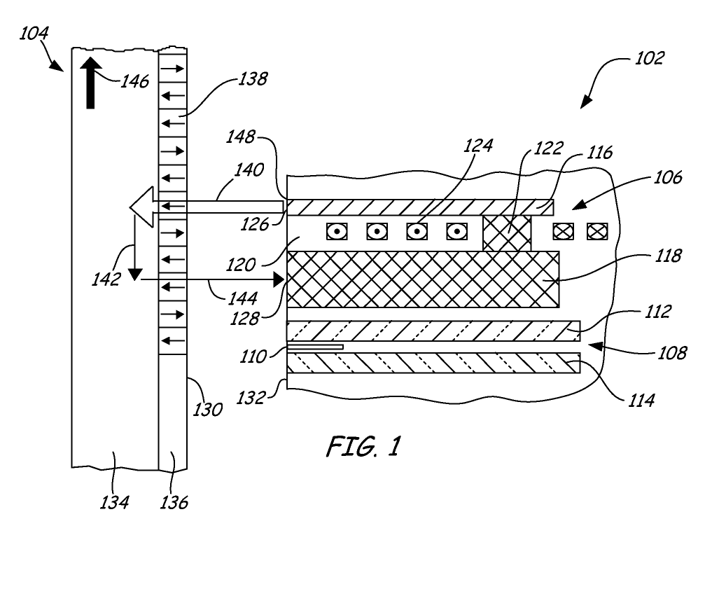

FIG. 1 illustrates a partial sectional view of one example read/write transducer 102 for recording to a medium 104. FIG. 1 illustrates perpendicular recording. However, it should be realized that other configurations are possible, such as longitudinal recording. In FIG. 1, all spacing and insulating layers are omitted for clarity. Read/write transducer 102 includes a writing element 106 and a reading element 108 formed on a trailing edge of a slider (not shown). Reading element 108 includes a read sensor 110 that is spaced between a top shield 112 and a bottom shield 114. Top and bottom shields 112 and 114 operate to isolate read sensor 110 from external magnetic fields that could affect sensing bits of data that have been recorded on medium 104.

Writing element 106 includes a writing main pole (or write pole) 116 and a return pole 118. Main and return poles 116 and 118 are separated by a non-magnetic spacer 120. Main pole 116 and return pole 118 are connected at a back gap closure 122. A conductive coil 124 extends between main pole 116 and return pole 118 and around back gap closure 122. An insulating material (not shown) electrically insulates conductive coils 124 from main and return poles 116 and 118. Main and return poles 116 and 118 include main and return pole tips 126 and 128, respectively, which face a surface 130 of medium 104 and form a portion of an air bearing surface (ABS) 132 of a slider. FIG. 1 illustrates reading element 108 having separate top and bottom shields 112 and 114 from writing element 206. However, it should be noted that in other read/write transducers, return pole 118 could operate as a top shield for reading element 108.

A magnetic circuit is formed in writing element 106 by return pole 118, back gap closure 122, main pole 116, and a soft magnetic layer 134 of medium 104 which underlay a hard magnetic or storage layer 136 having perpendicular orientation of magnetization. Storage layer 136 includes uniformly magnetized regions 138, each of which represent a bit of data in accordance with an up or down orientation. In operation, an electrical current is caused to flow in conductive coil 124, which induces a magnetic flux that is conducted through the magnetic circuit. The magnetic circuit causes the magnetic flux to travel vertically through the main pole tip 126 and storage layer 136 of the recording medium, as indicated by arrow 140. Next, the magnetic flux is directed horizontally through soft magnetic layer 134 of the recording medium, as indicated by arrow 142, then vertically back through storage layer 136 through return pole tip 128 of return pole 118, as indicated by arrow 144. Finally, the magnetic flux is conducted back to main pole 116 through back gap closure 122.

Main pole tip 126 is shaped to concentrate the magnetic flux traveling there through to such an extent that the orientation of magnetization in patterns 138 of storage layer 136 are forced into alignment with the writing magnetic field and, thus, cause bits of data to be recorded therein. In general, the magnetic field in storage layer 136 at main pole tip 126 must be twice the coercivity or saturation field of that layer. Medium 104 moves in the direction indicated by arrow 146. A trailing edge 148 of main pole 116 operates as a “writing edge” that defines the transitions between bits of data recorded in storage layer 136, since the field generated at that edge is the last to define the magnetization orientation in the pattern 138.

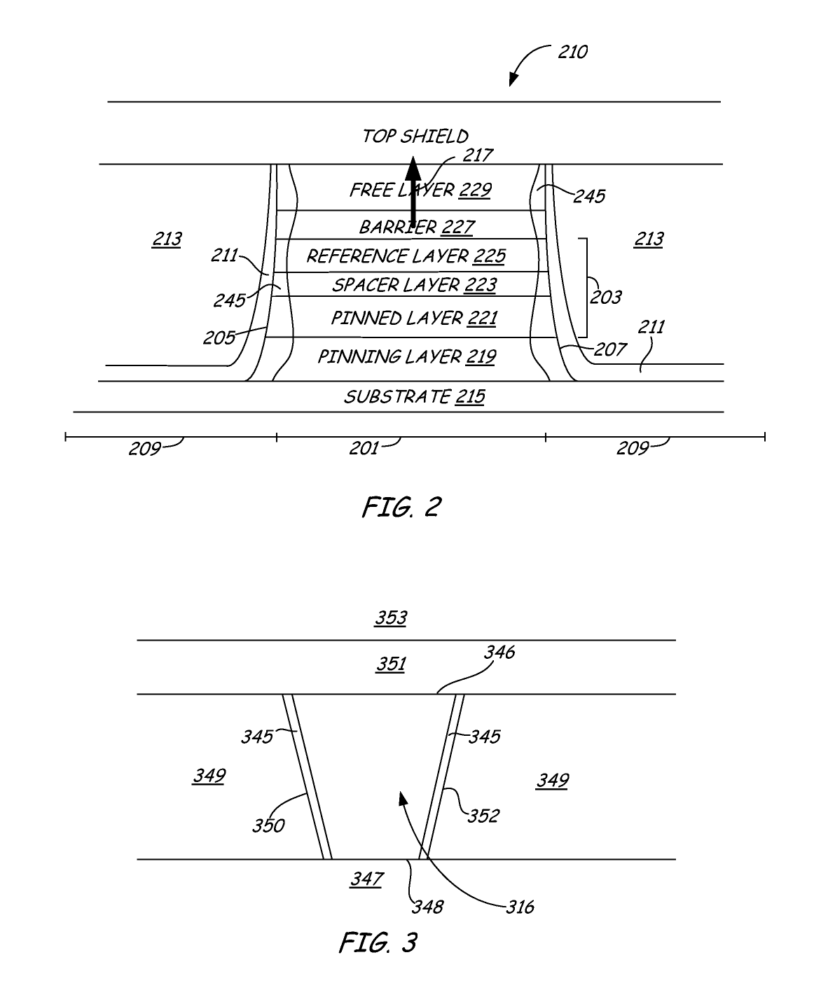

FIG. 2 is a diagrammatic air bearing surface (ABS) view of a sensor 210, similar to the read sensor 110 illustrated in FIG. 1, under one embodiment. Sensor 210 includes a substrate (or structure) 215. Sensor 210 includes active region 201 and passive region 209. Active region 201 contains a multiple-layered sensor stack or junction. The sensor stack includes sidewalls 205 and 207. Passive region 209 is the region that surrounds the multiple layered sensor stack on sidewalls 205 and 207.

In one embodiment of the active region 201, sensor stack includes a seed or substrate layer 215, a pinning layer 219, a pinned layer 221, a spacer (Ru) layer 223, a reference layer 225, a barrier layer 227, a free layer 229 and a cap layer (not specifically illustrated in FIG. 2). The pinned layer 221 is positioned on and exchange coupled with the underlying pinning layer 219. Pinned layer 221 includes a magnetic moment or magnetization direction that is substantially prevented from rotating in the presence of applied magnetic fields. Pinned layer 221 can comprise a ferromagnetic material, while pinning layer 219 can comprise an antiferromagnetic material. Other materials having similar properties are also possible.

In the FIG. 2 embodiment, the pinned layer 221, spacer layer 223 and reference layer 225 together can be considered a synthetic antiferromagnet (SAF) 203. SAF 203 includes two soft ferromagnetic layers (the pinned layer 221 and the reference layer 223) separated by the spacer layer 223, which can be a metal such as ruthenium (Ru) or rhodium (Rh). The reference layer 225 is the layer closest to the free layer 229. The exchange coupling between pinned layer 221 and the reference layer 225 is an oscillatory function of the thickness of spacer layer 223. The barrier layer 227 is positioned between the reference layer 225 and free layer 229. The free layer 229 can comprise a ferromagnetic material and is considered the “sensing” layer. The free layer 229 has a magnetization direction that is substantially free to rotate in the presence of externally applied magnetic fields.

Each passive region 209 of sensor 210 includes an insulating layer or isolation layer 211, biasing layer 213, such as a permanent magnet or any other material that provides a bias, and seed and cap layers (not shown). Insulating layer 211 surrounds the sensor stack or active region 201 of sensor 210. However, insulating layer 211 needs to at least surround the barrier layer. Sensor 210 includes a sensor current 217 that flows perpendicular to the stack length and through the barrier layer (one skilled in the art will appreciate that current can also be applied in a direction opposite from the direction illustrated in FIG. 2). The barrier layer needs to be insulated by a thick enough insulating layer to prevent current 217 from leaking into biasing layer 213, for example. An example insulating material includes aluminum oxide (Al₂O₃). However, other types of materials with similar properties are possible.

To properly bias and yet still allow the free layer to rotate in response to magnetic fields, bias layer 213 is formed on opposing sides of at least the free layer of sensor 210. Bias layer 213 is configured to induce a uniform pinning or biasing field across the free layer. The bias layer 213 is illustrated as being formed on opposing sides of the active region 201 of each sensor stack and placed outside of insulating material 211. However, bias layer 213 can be formed on opposing sides of at least the free layer of sensor 210. The bias layer 213 is configured to bias the free layer at edges (i.e. sides 205, 207) of the free layer to eliminate domain edges and at the same time leave a small field at the center of the free layer.

In the conventional fabrication of sensor 210, the layers of active region 201 are formed on the substrate 215. Then, the sensor stack is photo patterned to a desired critical dimension and then placed in an ion milling machine to define and shape sidewalls 205 and 207 using a photo resist mask. During ion milling, the sensor stack is bombarded with ions and can form damaged zones or dead layers 245. After ion milling, the sensor stack is pulled out of the machine and exposed to atmospheric conditions before transference to the next step for insulation layer formation. Upon exposure to atmosphere, even larger damaged zones or dead layers 245 are formed via the edge reaction with the ambient moisture and oxygen etc, which have an uncontrolled and varying thickness.

The damaged zones or dead layers formed can affect read performance. For example and particularly in small reader sensors, the resistance of the device may vary depending on the thickness of the dead layer and, therefore, the edge effect of the reader can be critical to read performance. More specifically, the sensor stack can lose control of resistance.

The sensor stack is then inserted into an isolation deposition machine to deposit and surround the sidewalls 205 and 207 of the sensor stack with an insulation or isolation material 211. Subsequent to the isolation step, the sensor stack is again taken out of the isolation deposition machine and inserted into a permanent magnet deposition machine to deposit a permanent magnet to surround the isolation material. Between deposition of the isolation material and deposition of the permanent magnet, if the sensor stack is taken out of vacuum, the surface of the isolation material can absorb oxygen and moisture. By depositing the permanent magnet on the surface of the isolation material, the permanent magnet can embed with and react with the oxygen and water to deteriorate its performance properties.

This effect is especially noted for high coercivity magnet (HCM) material, such as FePt, which has a thin platinum seed layer between the FePt and the isolation layer. Before annealing, the FePt layer can be easily oxidized, which cause its desirable magnetic properties to worsen. Although an additional step of cleaning the isolation layer after deposition is possible to remove absorbents on its surface from exposure to atmosphere, the additional cleaning step can increase the process time between the isolation deposition and the deposition of a permanent magnet. Moreover, the non-uniformity caused by such cleaning steps adds insulation layer thickness and thus device performance variation. In addition, before the absorbents can be cleaned, the absorbents can penetrate through a thin isolation layer and deteriorate sensor stack materials.

Finally, a top shield is deposited to cover the active region 201 as well as the passive region 209. In each of the steps after the sensor stack definition or shaping, exposure to atmosphere can cause further oxidation.

FIG. 3 is diagrammatic air bearing surface (ABS) view of a write pole 316, similar to the write pole 116 illustrated in FIG. 1, under one embodiment. Write pole 316 includes a trailing end 346 and a leading end 348 and is made of a magnetic material. The magnetic material of pole 316 is surrounded by alumina 347 on leading end 348 or bottom of pole 316 and by alumina 349 on the sidewalls 350 and 352 of pole 316. Sidewalls 350 and 352 are located between trailing end 346 and leading end 348. At the top or trailing end of pole 316 includes a writer gap 351 with a front shield 353 on top of the writer gap.

In the conventional fabrication of write pole 316, magnetic material is deposited on to a substrate (or structure) 347 with alumina coating. A photo resist/hard mask is deposited on top of the magnetic material such that the pole width can be defined and shaped. The substrate, magnetic material and photo resist are placed in an ion beam milling machine to perform pole definition. After ion milling, the material stack is pulled out of the machine and exposed to atmospheric environment. When exposing the material stack to atmosphere, the sidewalls 350 and 352, which are bombarded with ions during pole formation/shaping, are susceptible to moisture and oxygen attack, resulting in formation of reaction zones or dead layers 345 having an uncontrolled and varying thickness.

The photo resist is removed and the pole 316 is backfilled with alumina 349. After the pole 316 is backfilled, a chemical mechanical polishing process (CMP) is performed. After this process, a thick layer of alumina acting as the write gap 351 is deposited on pole 316 and magnetic material is deposited on the write gap to form the front shield 353.

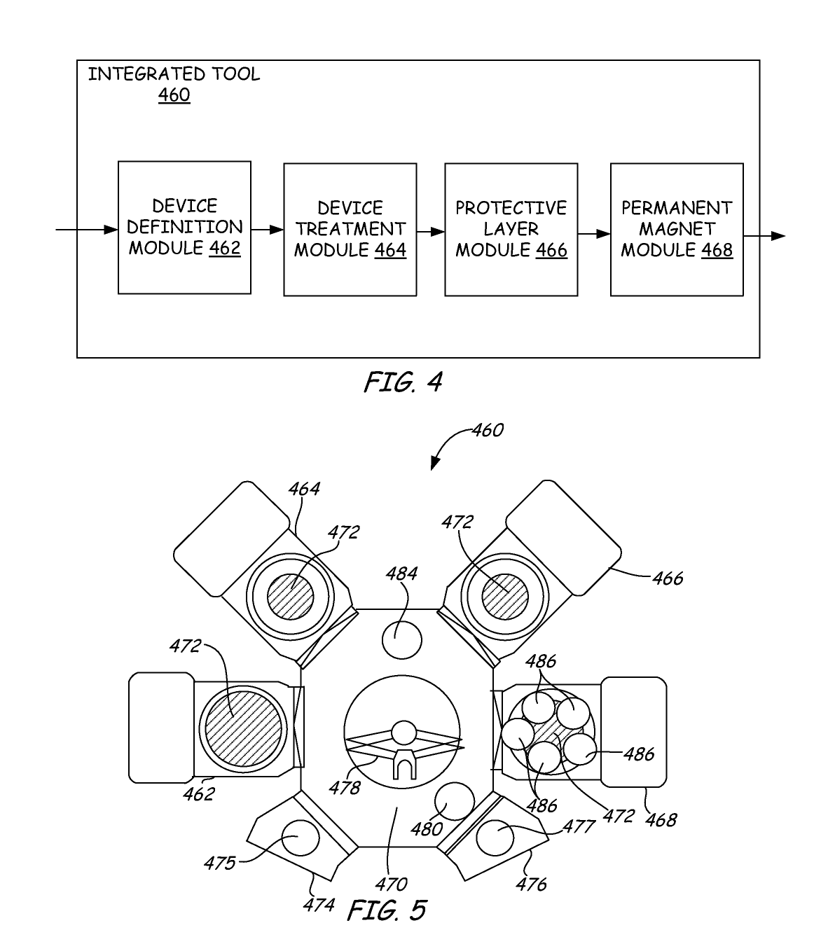

FIG. 4 illustrates a block diagram of an integrated tool 460 for forming one of a reader sensor, such as sensor 210 in FIG. 2, and a write pole, such as write pole 316 in FIG. 3, in such a way as to eliminate the formation of reaction zones or dead layers 245 and 345 on sidewalls of the read sensor or the write pole. Integrated tool 460 includes at least two modules. In FIG. 4, tool 460 includes four modules 462, 464, 466 and 468. It should be realized that while integrated tool 460 can include all four modules and more than four modules, integrated tool 460 need only have two modules. Each of the modules, such as modules 462, 464, 466 and 468, are all under a vacuum within integrated tool 460.

A magnetic structure that will be formed into a magnetic device or transducing device is placed in integrated tool 460 for formation. A magnetic structure includes layered magnetic material deposited on a structure or substrate. Such a structure is illustrated as 316 in FIG. 3 and includes the pinning, pinned, spacer, reference, barrier and free layers of sensor 210 deposited on substrate 347 After magnetic stack layer formation, the structure enters into tool 460 and into device definition module 462. In device definition module 462, the structure undergoes at least one shaping operation. For example, the structure can undergo ion beam etching (IBE), reactive ion etching (RIE), reactive ion beam etch (RIBE) and/or inductively-coupled plasma (ICP) etch in certain chemistry to take away magnetic material of the structure to define an appropriate width that corresponds to a width of a track in a storage medium. It should be realized that both reader sensor stacks as well as write poles undergo the processing step accomplished in device definition module 462.

IBE or RIE is an etching process in which the structure is milled or etched. In an embodiment where module 462 uses IBE, the structure is placed in front of a broad-beam ion source. Ions (for example argon ions) are generated inside the ion source and are accelerated, extracted from extraction grids on the front of the source, and directed towards the structure to be milled. The ions bombard the surface of the structure. As the ion beam etches the structure surface in the presence of a mask, the structure is tilted to a certain angle relative to the beam and rotated to optimize the uniformity of the etch and to create different device profiles.

RIBE is an etching process like IBE, except the ion source is somewhat different. In RIBE, reactive species, such as chlorine, fluorine, carbon fluoride and oxygen, are introduced into the conventional argon ion source. This process is partially chemical in that the ions react with the surface and form volatile byproducts and partially physical in that the material removal is truly via physical bombardment. RIE is a chemical etching process. Chemically reactive plasma is used to remove material from the structure. The reactive species are generated using an inductively couple plasma (ICP). These species are then accelerated towards the structure surface via structure stage biasing. The reaction byproducts will be either vaporized away from surface or removed via ion bombardment assistance.

In one embodiment, the structure can then be moved to device treatment module 464. Device treatment module 464 is an optional step for any type of structure, regardless if the structure is for a read sensor or write pole. Example treatments include a controlled passivation process, such as a controlled oxidation/reduction, a cleaning treatment, such as a sputter etch (i.e., “soft etch”) and other treatments, such as plasma exposure, heat and/or other type of gaseous exposure. A soft etch is one in which the surface is etched using an ionized gas plasma at lower energy. Treatments that can be performed in the treatment module 464 can repair surface or subsurface etch damage that were formed in the device definition module 462 from ion bombardment. Treatment module 464 can present a more uniform starting surface for protective layer growth and/or it can smooth the otherwise rough surfaces of the sidewalls of the structure.

In one embodiment, the structure can then be moved to protective layer or isolation layer deposition module 466. Again, module 466 is an optional step in the formation of the structure. In this module, regardless of the type of structure, a protective layer is deposited on the structure such that it is in contact with the sidewalls of the structure. In the case of a reader sensor, the protective layer is the isolation or insulating layer. Example isolation materials include oxides, nitrides, oxynitrides, fluorides, carbides or other insulators capable of controlled deposition below sensor stack damage thresholds. In the case of a write pole, the protective material can be non-magnetic materials, such as Ta, Ru, Cu or other similar materials that do not reduce the write pole surface layer magnetization and can prevent oxidation, or a metal/oxide combination layers. The deposition of isolation materials specific for reader sensors and the deposition of protective materials specific for write poles can be performed in module 466 in a variety of different techniques, including physical vapor deposition (PVD), ion beam deposition (IBD), atomic layer deposition (ALD), chemical vapor deposition (CVD), plasma enhanced chemical vapor deposition (PECVD), ionized physical vapor deposition (IPVD) and/or PVD sputtering.

PVD is a process of depositing a thin film by the condensation of a vaporized form of the material onto the surface of the structure. The following are some common types of PVD. In one example, evaporative deposition is the process where the material to be deposited is heated to a high vapor pressure by electrically resistive heating. In another example, electron beam physical vapor deposition is a process where the material to be deposited is heated to a high vapor pressure by electron bombardment. In yet another example, magnetron sputter deposition is a process where a glow plasma discharge (usually localized around the “target” by a magnet) bombards the material causing the sputtering of some away as a vapor. In still another example, IPVD refers to the same process as PVD. However, in IPVD, the deposition flux consists of more ions than neutrals.

IBD is a process of ejecting material from a target and condensing it onto the structure using a focused ion beam. The impingement ions eject atoms out of a solid material from a target surface, which are then condensed ion onto the structure surface to form desired layer thickness. ALD is a process of growing material layers on a structure. ALD is based on the sequential exposure of gas phase chemistry onto the structure surface. The mono-layer absorption capability of structure surface under each chemistry exposure enables the formation of a true atomic-level of film depositions and superior step coverage of sharp features. The majority of ALD reactions use two chemicals, typically called precursors. These precursors react with a growth surface of a structure in a sequential manner. By exposing the precursors to the growth surface repeatedly, a thin film is deposited. CVD is the chemical process of introducing one or more volatile precursors into a reaction chamber, which react and/or decompose and form the desired film on the structure surface. Frequently, the volatile by-products of the precursors are removed by pumping the system through a reaction chamber.

In one embodiment, after deposition of the protective layer, the structure can be moved to permanent magnet deposition module 468 in the case where the structure is a reader sensor. In the permanent magnet deposition module 468, a biasing material or permanent magnet is deposited on the isolation or insulating layer. The deposition of the permanent magnet specific for reader sensors and a subsequent protective capping layer can be performed in module 468 in a variety of different techniques, including PVD, IBD, and/or point cusp magnetron sputtering (PCM). After deposition of the protective layer, the structure is moved out of tool 460. Its definition and protection from the formation of dead layers and reaction zones is complete.

FIG. 5 illustrates diagrammatic view of integrated tool 460. As illustrated in FIG. 5, the four modules 462, 464, 466 and 468 are all coupled together by a transfer chamber or module 470. As previously discussed, integrated tool 460 need only includes at least two modules.

A structure 472 (illustrated in FIG. 5 as progressing through each of modules 462, 464, 466 and 468) enters tool 460 through an input load lock 474. For example, in the case of a reader sensor, a structure having the layered sensor stack with a photo resist on top is placed into the input port. In the case of a write pole, a structure having layers of magnetic material and a photo resist on top is placed in the input port. Structure 472 exits tool 460 at an output load lock 476. Output load lock 476 includes an empty slot space 477 for placing the structure after it has undergone definition and formation in tool 460. Between the input load lock 474 and output load lock 476, the structure will be under vacuum.

Transfer chamber 470 includes a robotic arm 478. To make sure structure 472 is properly aligned, robotic arm 478 is configured to first move structure 472 from input load lock 474 to an alignment chuck 480. Although alignment chuck 480 is illustrated as being located near output load lock 476, alignment chuck 480 can be located other places within transfer chamber 470. Alignment chuck 480 spins the structure with a motor to properly align a notch in the structure so it is in proper position for transfer. After alignment, robotic arm 478 is configured to move the structure 472 from alignment chuck 480 into device definition module 462.

As previously discussed, in device definition module 462, the structure undergoes at least one shaping operation. After device definition, the robotic arm 478 retrieves structure 472 from device definition module 462 and optionally transfers it to device treatment module 464. Before transferring structure 472 to module 464, the structure may need to undergo some form of preheating. In such a case, robotic arm 478 transfers the structure to a heating chuck 484. By placing the structure in heating chuck 484, less time is needed for the device 472 to spend in processing modules 464 to warm to the device to the correct pre-set temperature. It should be realized that the structure 472 can be heated for any of the processes performed in any of modules 464, 466 and 468 if necessary. Therefore, if the structure 472 skips treatment and moves directly to module 466 for protective layer deposition, the structure 472 may also need to heat to the certain temperature in the heating chuck 484 for throughput and performance control.

After optionally undergoing device treatment in module 464, the structure is retrieved from module 464 by robotic arm 478 and moved to protective layer or isolation layer deposition module 466. In this module, regardless of the type of structure, a protective layer is deposited on the structure such that the protective layer is in contact with its sidewalls.

After deposition of the protective layer, the structure is retrieved by robotic arm 478 and optionally moved to permanent magnet deposition module 468. The processing steps taking place in module 468 are those steps needed where the structure is a reader sensor. Otherwise, in the case of a write pole, the structure 472 is robotically transferred to the output load lock 476. Its definition and protection from the formation of dead layers is complete.

In the permanent magnet deposition module 468, a permanent magnet is deposited on the isolation or insulating layer. As illustrated in FIG. 5, permanent magnet deposition module 468 includes a plurality of different materials 486 needed in the process of depositing the permanent magnet. After the permanent magnet is deposited, robotic arm 478 retrieves the structure and transfers it to empty space 477 in output load lock 476. The structure 472 definition and protection from the formation of dead layers and reaction zones is complete.

Structure 472 may undergo processes in tool 460 in a variety of different sequential operations and a variety of different types of treatments depending on the use of the structure to be fabricated. In one embodiment, structure 472 may undergo device definition with module 462, device treatment using module 464 including a cleaning treatment and a passivation treatment, protective layer or isolation layer deposition in module 466 and permanent magnet deposition in module 468. In another embodiment, a device may undergo device definition with module 462, device treatment using module 464 including just a cleaning treatment, protective layer or isolation layer deposition in module 466 and permanent magnet deposition in module 468. In another embodiment, a device may undergo device definition with module 462, device treatment using module 464 including a cleaning treatment and a passivation treatment and a permanent magnet deposition in module 468. In this embodiment, there is no protective layer deposition.

In another embodiment, a device may undergo device definition with module 462, protective layer or isolation layer deposition in module 466 and permanent magnet deposition in module 468. In this embodiment, there is no intermediate treatment step. In another embodiment, a device may undergo device definition with module 462, device treatment using module 464 including a cleaning treatment and a passivation treatment and a protective layer or isolation layer deposition in module 466. In this embodiment, there is no permanent magnet deposition. In another embodiment, a device may undergo device definition with module 462, device treatment using module 464 including just a cleaning treatment and a protective layer or isolation layer deposition in module 466. In this embodiment, there is no permanent magnet deposition. In another embodiment, a device may undergo device definition with module 462 and device treatment using module 464 including a cleaning treatment and a passivation treatment. In this embodiment, there is no protective layer deposition or permanent magnet deposition. In another embodiment, a device may undergo device definition with module 462 and a protective layer or isolation layer deposition in module 466. In this embodiment, there is no intermediate treatment step or permanent magnet deposition.

Of the above described embodiments, a reader sensor would preferably undergo device definition with module 462 using an IBE technique, device treatment module 464 including a cleaning treatment using a soft etch and a passivation treatment, such as oxidation, protective layer or isolation layer deposition with module 466 using an ALD technique and permanent magnet deposition with module 468 using an IBD technique. A write pole would preferably undergo device definition with module 462 using an IBE technique and protective layer or isolation layer deposition with module 466 using a CVD or ALD technique.

With the integration of a protective layer or isolation layer deposition module 466 with a device definition module 462 and permanent magnet deposition module 468 in vacuum, there is no need to clean the protective layer or isolation layer surface or to worry about sensor stack oxidation from air. In all, a reader sensor would benefit from a permanent magnet having better magnetic properties, high throughput and full protection for sensor stack. With the integration of a protective layer or isolation layer deposition module 466 and a device definition module 462 in vacuum, prevention of the formation of reaction zones or dead layers on the sidewalls of either a reader sensor or a write pole occurs.

Beside tool 460 providing the minimization of edge reaction zones of a transducing device by integrating both device definition and subsequent protective layer deposition in an integrated tool without breaking vacuum, tool 460 also provides for more time efficient fabrication of transducing devices. Tool 460 can process many structures at the same time. For example, while a structure is being processed in device definition module 462, other structures can be processing in any of modules 464, 466 and 468. In addition, structure can reside in alignment chuck 480 and heating chuck 484 indefinitely while waiting to enter any of modules 462, 464, 466 and 468 if there are structures inside such modules.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A tool for use in fabricating an electronic component comprising:
a plurality of processing modules;
a transfer chamber in communication with each of the plurality of processing modules and having a robotically moveable arm for transferring a structure to each of the plurality of processing modules;
wherein the plurality of processing modules and the transfer chamber are sealed from the surrounding environment and are under a vacuum, the plurality of processing modules including:
a first module configured to perform a first process, wherein the first process includes performing at least one shaping operation on the structure; and
a second module configured to perform a second process.

2. The tool of claim 1, further comprising an input load lock configured to receive the structure from the surrounding environment and an output load lock configured for sending the structure back into the surrounding environment after being processed by at least one of the plurality of processing modules, the robotically moveable arm configured to retrieve the structure from the input load lock and transfer the structure to one of the plurality of processing modules and the robotically moveable arm configured to retrieve the structure from one of the plurality of processing modules and transfer the structure to the output load lock.

3. The tool of claim 2, further comprising an alignment chuck, wherein when the robotically moveable arm retrieves the structure from the input load lock, the robotically moveable arm is configured to transfer the structure to the alignment chuck to align the structure prior to transferring the structure to one of the plurality of processing modules.

4. The tool of claim 1, further comprising a heating chuck, wherein the robotically moveable arm transfers the structure into the heating chuck to pre-heat the structure before the structure is transferred into one of the plurality of processing modules for processing.

5. The tool of claim 1, wherein the second process performed in the second module comprises a process of treating sidewalls of the structure using at least one of a cleaning treatment and a passivation treatment.

6. The tool of claim 5, wherein the plurality of processing modules further comprise a third module configured to perform a third process, wherein the third process includes forming a protective material on the structure such that the protective material is in contact at least some of the sidewalls of the structure.

7. The tool of claim 6, wherein the plurality of processing modules further comprise a fourth module configure to perform a fourth process, wherein the fourth process includes forming biasing material on the protective material that was formed on the structure with the third module.

8. The tool of claim 5, wherein the plurality of processing modules further comprise a third module configured to perform a third process, wherein the third process includes forming biasing material on the structure with the third module.

9. The tool of claim 1, wherein the second process performed in the second module comprises a process of forming a protective material on the structure such that the protective material is in contact at least some of the sidewalls of the structure.

10. The tool of claim 9, wherein the plurality of processing modules further comprise a third module configured to perform a third process, wherein the third process includes forming biasing material on the structure with the third module.

11. A method of fabricating an electronic component comprising:
forming a structure by depositing layered magnetic material on a substrate, the layered magnetic material including a trailing edge, a leading edge and a pair of opposing sidewalls extending between the trailing edge and the leading edge;
placing the structure in a tool, the tool including a plurality of processing modules and a transfer chamber in communication with each of the plurality of processing modules and having a component for transferring the structure to each of the plurality of processing modules, wherein the plurality of processing modules and the transfer chamber are sealed from the surrounding environment and are under a vacuum;
transferring the structure from the transfer chamber into a first module of the plurality of processing modules, the first module configured to perform a first process on the structure, the first process including defining the structure by performing at least one shaping operation on the structure; and
transferring the structure from the first module to a second module of the plurality of processing modules, the second module configured to perform a second process on the structure.

12. The tool of claim 11, wherein the second process performed in the second module comprises treating the pair of opposing sidewalls of the structure using at least one of a cleaning treatment and a passivation treatment.

13. The tool of claim 12, further comprising transferring the structure from the second module to a third module of the plurality of processing modules, the third module configured to perform a third process on the structure, the third process including forming a protective material on the structure such that the protective material is in contact the pair of opposing sidewalls of the layered magnetic material.

14. The tool of claim 13, further comprising transferring the structure from the third module to a fourth module of the plurality of processing modules, the fourth module configure to perform a fourth process, the fourth process including forming biasing material on the protective material that was formed on the structure with the third module.

15. The tool of claim 12, further comprising transferring the structure from the second module to a third module of the plurality of processing modules, the third module configured to perform a third process on the structure, the third process including forming biasing material on the structure with the third module.

16. The tool of claim 11, wherein the second process performed in the second module comprises forming a protective material on the structure such that the protective material is in contact with the pair of opposing sidewalls of the layered magnetic material.

17. The tool of claim 16, further comprising transferring the structure from the second module to a third module of the plurality of processing modules, the third module configured to perform a third process on the structure, the third process including forming biasing material on the structure with the third module.

18. A tool for use in fabricating an electronic component comprising:
a plurality of processing modules;
a transfer chamber in communication with each of the plurality of processing modules and having a robotically moveable arm for transferring a structure to each of the plurality of processing modules, the structure including layered magnetic material formed on a substrate, the layered magnetic material including a trailing edge, a leading edge and a pair of opposing sidewalls extending between the trailing edge and the leading edge;
wherein the plurality of processing modules and the transfer chamber are sealed from the surrounding environment and are under a vacuum, the plurality of processing modules including:
a first module configured to perform a first process on the structure, wherein the first process includes performing at least one shaping operation on the pair of opposing sidewalls of the layered magnetic device; and
a second module configured to perform a second process on the structure, wherein the second process includes depositing a protective material on at least the pair of opposing sidewalls of the layered magnetic device.

19. The tool of claim 18, wherein the first process utilizes one of a ion beam etching (IBE), reactive ion etching (RIE), reactive ion beam etch (RIBE) and inductively-coupled plasma (ICP) etch to perform the at least one shaping operation.

20. The tool of claim 18, wherein the second process utilizes one of a physical vapor deposition (PVD), ion beam deposition (IBD), atomic layer deposition (ALD), chemical vapor deposition (CVD), and plasma enhanced chemical vapor deposition (PECVD) to deposit the protective material on at the pair of opposing sidewalls of the layered magnetic device.
